(19) United States
(12) Patent Application Publication
(10) Pub. No.: US 2007/0152314 A1
(43) Pub. Date: Jul. 5, 2007

(54) Low stress stacked die packages

(75) Inventors: Rahul Manepalli, Chandler, AZ (US); Amram Eitan, (US); Prasanna Raghavan, (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/323,204

(22) Filed: Dec. 30, 2005

(51) Int. Cl. H01L 23/02; H01L 21/50

(52) U.S. Cl. 257/686; 438/109; 257/E23.085

(57) ABSTRACT

A stacked die package comprises a first die on a substrate, a die attach layer superjacent to the first die, and a second die on the die attach layer. The die attach layer comprises a die attach material having a glass transition temperature substantially in the range of 150-180° C. Raising the glass transition temperature reduces the mismatch in the coefficients of thermal expansion (CTE) between the die attach and the mold compound that surrounds the first die in the package.

### BACKGROUND

1. Field

Semiconductor packaging.

2. Background

A recent development in semiconductor packaging is the stacked die package, in which multiple dice are packaged together in a vertical stack. A stacked die package effectively increases the device functionality within the same footprint as a single die package. Thus, utilization of package space is greatly improved.

A stacked die package typically includes a spacer between two active dice in the stack to separate the dice. The spacer is attached to each die using a die attach material, which may be an adhesive material or hard solders. The spacer is typically smaller than each die to allow wire bonding on the die periphery. A mold compound placed over the stacked dice, the spacer, and the bonding wires immobilizes these components after a curing process. As a result, an interface of three different materials (die, die attach, and mold compound) is formed on the surface of the active die located below the spacer. The interface of the different materials produces a non-uniform stress on the active die, which may lead to damages to the die and result in a non-functioning die.

### BRIEF DESCRIPTION OF THE DRAWINGS

Embodiments are illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

FIG. 1 is a diagram of an embodiment of a stacked die package as viewed from a wire-bond side.

FIG. 2 is a diagram of the stacked die package as viewed from a non-wire-bond side.

FIG. 3 shows a simulation result of stress reduction at the wire-bond side using a die attach material that has thermo-mechanical properties similar to those of a mold compound.

FIG. 4 shows a simulation result of stress reduction at the non-wire-bond side using the die attach material of FIG. 3.

FIG. 5 is a cross-sectional view of an embodiment of an integrated circuit package comprising the stacked die package of FIG. 1 and FIG. 2.

### DETAILED DESCRIPTION

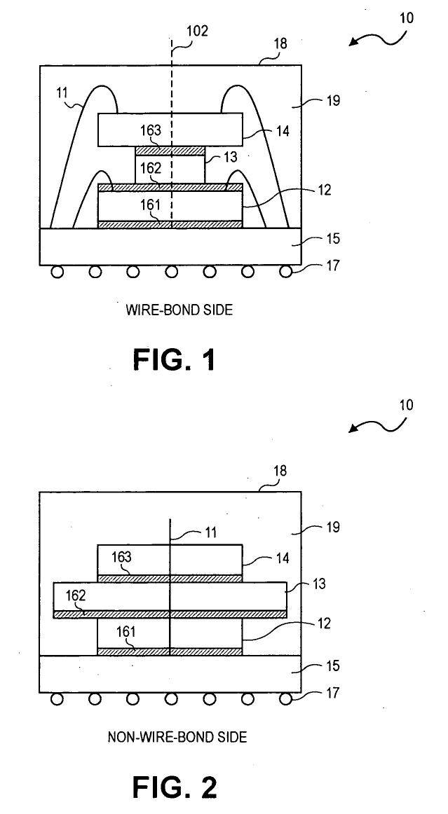

FIG. 1 shows an embodiment of a semiconductor package 10 as viewed from a wire-bond side of the package. FIG. 2 shows semiconductor package 10 as viewed from a non-wire-bond side (or overhang side) of the package, by rotating the package 90 degrees with respect to a vertical axis 102. Semiconductor package 10 includes a first die 12 and a second die 14 vertically stacked to form a stacked die package. Between first die 12 and second die 14 is a spacer 13 comprising inactive silicon to separate the two dice. Spacer 13 protrudes from both sides of die 12 and die 14 as shown in FIG. 2. First die 12 is mounted on a package substrate 15 using an adhesive die attach layer 161. Die attach layers 162 and 163 similarly serve to hold spacer 13 and second die 14 in place. Die attach layers 161, 162, and 163 may comprise the same die attach material 16, which may be any resin system that provides high glass transition temperature (Tg), low moisture uptake, and high temperature stability.

Both sides of die 12 and die 14 are electrically coupled to substrate 15 via bonding wires 11. A plurality of contact points 17 (e.g., leads) are attached to substrate 15 to conduct electrical currents flowing in and out of package 10. A casing 18 comprising ceramics, plastics, or any other suitable material encapsulates package 10 and the components therein. A mold compound 19 fills the entire unoccupied region inside casing 18 to immobilize the components therein. An example of mold compound 19 may be epoxy filled with silica (SiO₂).

It should be understood, however, the discussion that follows applies equally to stacked die packages having varied structures from the embodiment as shown. For example, package 10 may include more than two stacked dice. One or more of the dice may be coupled to bonding wires at any part of the die periphery. One or more of the dice may be wire-bond all around the periphery and thus do not have a non-wire-bond side.

As active circuits exist near the top surface of the die relative to the orientation of the package shown in FIG. 1 and FIG. 2, it is desirable to ensure the top surface of a die does not suffer from excess stress. Such stress may be caused by the top surface interfacing with multiple materials having different coefficients of thermal expansion (CTE). For example, if die attach layer 162 were to cover only the bottom portion of spacer 13, the portion of the top surface of first die 12 not covered by die attach layer 162 would be in direct contact with mold compound 19. Thus, the top surface of first die 12 would be in contact with two different materials having mismatched CTE. The difference in the CTE may cause excessive compressive stress on the top surface of first die 12 during the packaging process. During the molding stage of the packaging process, mold compound 19 is cured in a mold in a high temperature, e.g., 175° C. After the compound is hardened, it is taken out of the mold to be cooled down to the room temperature. Excess stress due to the temperature change may cause formation of cracks in the materials and result in failure of the packaged device.

In the embodiment of FIG. 1 and FIG. 2, as the top surface of second die 14 is in contact with only mold compound 19, the second die does not have the CTE mismatch problem as described above. However, in a typical stacked die package, a plurality of the dice may be stacked in the same package. Each die in the stack, except the top die, may have a superjacent die attach layer covering the entire top surface of the die to avoid the CTE mismatch problem. These superjacent die attach layers may all comprise die attach material 16. The term “superjacent” used herein refers to a structure on top of and in contact with another structure, relative to the orientation of the package shown in FIG. 1 and FIG. 2. The term “on” or “on top of,” relative to the same orientation, refers to a structure above another structure, wherein one or more intervening layers may or may not be present between the two structures.

In the embodiment as shown in FIG. 1 and FIG. 2, die attach layer 162 completely covers the active surface (top surface) of first die 12, including the wire-bonded regions, to isolate the top surface from mold compound 19. Bonding wires 11 extend through die attach layer 162. As a result, mold compound 19 does not interact with first die 12, leading to reduction in stress near the edge of first die 12 where spacer 13 and die attach layer 162 meet.

To ensure that die attach layer 162 extends to the edge of first die 12, die attach material 16 may be chosen to be a flowable material, before cured, that has suitable flow and wetting characteristics. For example, die attach material 16 may contain low molecular weight epoxies or rubber tougheners.

The non-uniform stress on the active surface of first die 12 may also be reduced by optimizing the material properties of die attach material 16. A typical silicon-based die has a CTE of approximately 3-5 parts per million per centigrade (ppm/C). Referring to Table 1, a typical die attach material may have a CTE of 80-120 ppm/C below the glass transition temperature (Tg) and a CTE of 200-400 ppm/C above Tg, wherein Tg is in the rage of 20-100° C. Mold compound 19 typically has a CTE of 7-15 ppm/C below Tg and a CTE of 30-60 ppm/C above Tg, wherein Tg is in the range of 150-175° C. Thus, the CTE for a typical die attach material is drastically different from the CTE of mold compound 19. The mismatch induces severe stresses on the die.

The stress on the active surface of first die 12 may also be related to the difference in elasticity between a typical die attach material and mold compound 19. Elasticity may be measured by elastic modulus (E) which indicates the ability of a material to withstand stress. Table 1 shows that the difference in elasticity between a typical die attach material and mold compound 19 is less when the temperature is below their respective Tg than above their respective Tg. Thus, to reduce stress, die attach material 16 may be chosen to have thermo-mechanical properties, e.g., Tg and CTE, similar to those of mold compound 19.

TABLE 1
Typical properties of die attach and mold compound materials

| Property | Die Attach | Mold Compound |
|---|---|---|
| Tg | 20° C.-100° C. | 150-175° C. |
| CTE ppm/C. < Tg | 80-120 | 7-15 |
| CTE ppm/C. > Tg | 200-400 | 30-60 |
| E < Tg | <3 Gpa | 18-25 GPa |
| E > Tg | 10-100 MPa | <3 GPa |

In one embodiment, die attach material 16 may have a higher Tg and a lower CTE than the typical ranges shown in Table 1. For example, Tg of the cured die attach material 16 may be in the range of approximately 150-180° C. Moreover, die attach material 16 may, but is not required to, include silica (SiO₂) or other filler materials to reduce the CTE. For example, die attach material 16 may contain silica filler up to 85% by weight. Die attach material 16 may be epoxy-based (e.g., epoxy-phenol, epoxy-amine), polyimides, or silicon-based (e.g., glass). Additives such as coupling agents, rheology modifiers and catalysts such as imidazoles, amines may be added to ensure flow characteristics, to prevent filler-resin separation, and to control the reaction kinetics of the die attach material.

In the following, two examples are provided to show compositions of die attach material 16. It should be understood that the weights and the chemical components may vary from the examples as long as the resulting Tg is raised to the range of approximately 150-180° C.

### EXAMPLE I

For example, die attach material 16 may comprise bisphenol F epoxy resin approximately 30% by weight, multifunctional phenol approximately 30% by weight, filler (e.g., fused silica) approximately 30% by weight, catalyst (e.g., imidazole) approximately 2% by weight, amino proply trimethoxy silane approximately 3% by weight, and carboxyl terminated butadiene rubber approximately 5% by weight.

### EXAMPLE II

In another example, die attach material 16 may comprise pre-imidized polyimide (biphenyl tetracarboxycilic di anhydride-oxydianiline, co polymerized with amine terminated siloxane) approximately 60% by weight, bisphenol F epoxy resin approximately 10% by weight, oxydianline approximately 15% by weight, catalyst (e.g., imidazole) approximately 1% by weight, amino proply trimethoxy silane approximately 3% by weight, filler (fused silica) approximately 11% by weight.

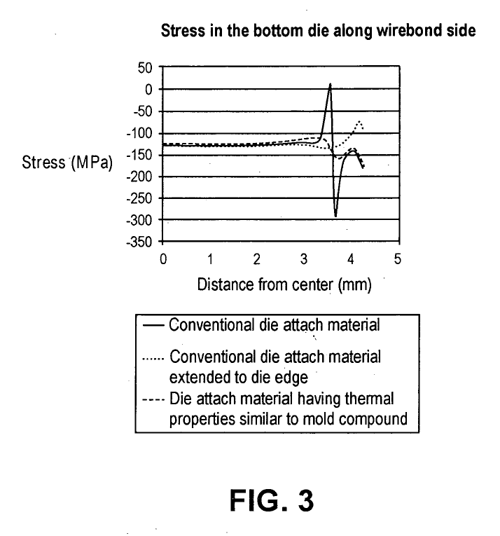

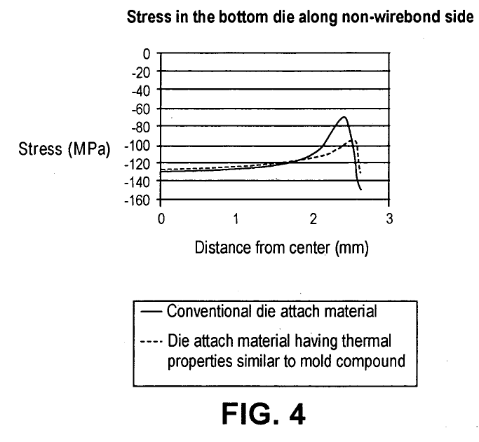

With reference to the package shown in FIG. 1 and FIG. 2, FIG. 3 and FIG. 4 shows simulation results of stress reduction at the wire-bond side and the non-wire-bond side, respectively. The simulation uses finite element analysis by comparing three different scenarios: (i) a conventional die attach material (e.g., the die attach material shown in Table 1) covering the bottom of spacer 13 only; (ii) the conventional die attach material covering the entire top surface of first die 12; and (iii) a die attach material having thermo-mechanical properties similar to those of mold compound 19 (e.g., the materials discussion in Examples I and II) and covering the top surface of first die 12. The results show that scenario (i) has the worse stress near the junction of mold compound 19 and the die attach material. Scenario (iii) achieves 80% reduction in the peak to peak stress at the wire-bond side and 60% reduction in the peak to peak stress at the non-wire-bond side.

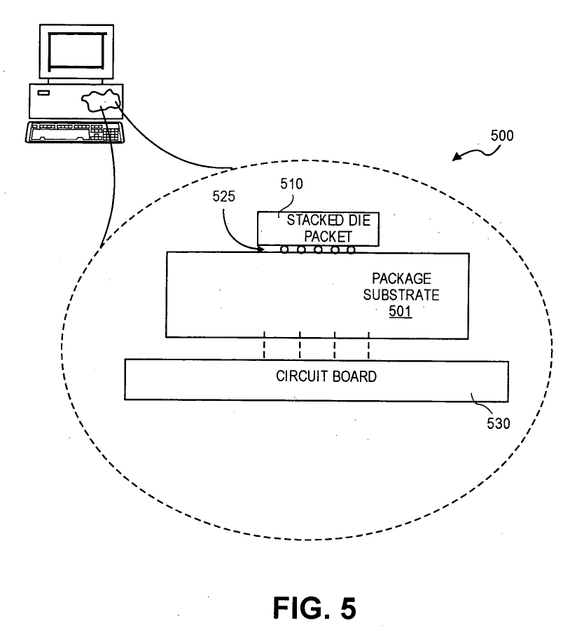

FIG. 5 shows a cross-sectional side view of an integrated circuit package that can be physically and electrically connected to a printed wiring board or printed circuit board (PCB) to form an electronic assembly. The electronic assembly can be part of an electronic system such as a computer (e.g., desktop, laptop, hand-held, server, etc.), wireless communication device (e.g., cellular phone, cordless phone, pager, etc.), computer-related peripheral (e.g., printers, scanners, monitors, etc.), entertainment device (e.g., television, radio, stereo, tape and compact disc player, videocassette recorder, MP3 (Motion Picture Experts Group, Audio Layer 3) player, etc.), and the like. FIG. 5 illustrates the package as part of a desktop computer.

FIG. 5 shows an electronic assembly 500 including a stacked die package 510 physically and electrically connected to a package substrate 501. Stacked die package 510 includes an integrated circuit die, such as a processor die. In one embodiment, stacked die package 510 includes die attach layer 162 of FIG. 1 comprising die attach material 16. Electrical contact points (e.g., contact pads on a surface of stacked die package 510) are connected to package substrate 501 through conductive bump layer 525. Package substrate 501 may be used to connect electronic assembly 500 to printed circuit board 530, such as a motherboard or other circuit board.

In the foregoing specification, specific embodiments have been described. It will, however, be evident that various modifications and changes can be made thereto without departing from the broader spirit and scope of the appended claims. The specification and drawings are, accordingly, to be regarded in an illustrative rather than a restrictive sense.

1. An apparatus comprising:
a first die on a substrate;
a die attach layer superjacent to the first die;
a second die on the die attach layer; and
a mold compound formed over the first die, the die attach layer, and the second
wherein the die attach layer comprises a die attach material having a glass transition temperature substantially matches the glass transition temperature of the mold compound.

2. The apparatus of claim 1 wherein the die attach materiel comprises silica filler up to 85% by weight.

3. The apparatus of claim 1 wherein the die attach material comprises epoxy-based resin.

4. The apparatus of claim 1 wherein the die attach material comprises polymide.

5. The apparatus of claim 1 wherein the die attach material comprises a silicon-based material.

6. The apparatus of claim 1 wherein the die attach material includes low molecular weight epoxies or rubber tougheners.

7. The apparatus of claim 1 wherein the die attach layer covers an entire top surface of the first die.

8-20. (canceled)

21. The apparatus of claim 1, wherein the glass transition temperature of the die attach material is substantially in the range of 150-180° C.
